(19) United States
(12) Patent Application Publication
(10) Pub. No.: US 2026/0240028 A1
(43) Pub. Date: Aug. 13, 2026

(54) BONDING METHOD USING A VARIABLE THICKNESS LAYER

(71) Applicant: Tokyo Electron Limited, Tokyo (JP)

(72) Inventors: Christopher Michael Netzband, Albany, NY (US); Michael Murphy, Niskayuna, NY (US); Ilseok Son, Albany, NY (US)

(21) Appl. No.: 19/053,296

(22) Filed: Feb. 13, 2025

(51) Int. Cl. H01L 23/00

(52) U.S. Cl. CPC H10W 72/073; H10W 72/013; H10W 72/0711; H10W 72/01323; H10W 72/07183; H10W 72/07331

(57) ABSTRACT

A method for bonding wafers includes depositing a dielectric layer on a first side of a first wafer, the dielectric layer including a first thickness at a first location and a second thickness at a second location, and loading the first wafer on a planar surface of a first wafer holder, the first wafer holder including concentric chucking zones. The method further includes activating the concentric chucking zones to align an outer surface of the dielectric layer with the planar surface of the first wafer holder while stretching the first wafer, and aligning a second wafer on a second wafer holder opposite the first wafer. And the method further includes bonding the first wafer with the second wafer to form a bonded wafer by striking the second wafer towards the first wafer to stretch the second wafer complimentary with the stretching of the first wafer.

### TECHNICAL FIELD

The present invention relates generally to a system and method for bonding wafers, and, in particular embodiments, to a system and method for bonding wafers using a variable thickness layer for scaling compensation.

### BACKGROUND

Wafer-to-wafer (W2W) bonding is a process in semiconductor manufacturing where two semiconductor wafers are precisely aligned and bonded together. During the bonding process, one wafer is struck which stretches the wafer to overcome the gap between the two wafers to initiate bonding. As semiconductor devices continue to shrink, the alignment of the wafers for wafer bonding becomes a challenge. Current manufacturing processes target total bonding misalignment of less than 30 nanometers.

### SUMMARY

In accordance with an embodiment of this disclosure, a method for bonding wafers includes depositing a dielectric layer on a first side of a first wafer, the dielectric layer including a first thickness at a first location and a second thickness at a second location, the first thickness being different from the second thickness, and loading the first wafer on a planar surface of a first wafer holder, the first wafer holder including concentric chucking zones. The method further includes activating the concentric chucking zones from a center to an outer edge of the first wafer holder to align an outer surface of the dielectric layer with the planar surface of the first wafer holder while stretching the first wafer, and aligning a second wafer on a second wafer holder opposite the first wafer, the second wafer being separated from the first wafer by a separation distance. And the method further includes bonding the first wafer with the second wafer to form a bonded wafer, the bonding including striking the second wafer towards the first wafer to stretch the second wafer complimentary with the stretching of the first wafer.

In accordance with another embodiment of this disclosure, a method for bonding a wafer includes receiving the wafer such that a backside of the wafer faces a processing nozzle, the wafer including a uniform thickness shape disposed over the backside of the wafer. The method further includes, while rotating the wafer, dispensing a processing solution over the backside of the wafer from the processing nozzle to form a variable thickness layer covering the backside of the wafer, the variable thickness layer including a first region including a first thickness, a second region including a second thickness, and a transition region including a variable thickness that smoothly transitions between the first thickness and the second thickness. And the method further includes loading the wafer on a wafer holder by sequentially activating concentric chucking zones from a center to an outer edge of the wafer holder such that the variable thickness layer contacts the wafer holder and flattens to form a symmetrical stretch in the wafer, and bonding the wafer with a second wafer to form a bonded wafer.

And in accordance with yet another embodiment of this disclosure, a system for bonding wafers includes a bonding chamber including a second wafer holder disposed over a first wafer holder, the second wafer holder including a striker disposed in a center of the second wafer holder, the first wafer holder including concentric chucking zones, and a controller coupled to the bonding chamber, the first wafer holder, the second wafer holder, and a memory storing instructions to be executed in the controller. The instructions when executed cause the controller to deposit a dielectric layer on a first side of a first wafer, the dielectric layer including a first thickness at a first location and a second thickness at a second location, the first thickness being different from the second thickness, load the first wafer on a planar surface of the first wafer holder, activate the concentric chucking zones from a center to an outer edge of the first wafer holder to align an outer surface of the dielectric layer with the planar surface of the first wafer holder while stretching the first wafer, align a second wafer on the second wafer holder opposite the first wafer, the second wafer being separated from the first wafer by a separation distance, and bond the first wafer with the second wafer to form a bonded wafer, the bonding including striking the second wafer towards the first wafer to stretch the second wafer complimentary with the stretching of the first wafer using the striker.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1J illustrate wafers during various steps of a wafer bonding method in accordance with an embodiment of this disclosure;

FIG. 2 is a flowchart illustrating a wafer bonding method in accordance with an embodiment of this disclosure;

FIGS. 3A-3C illustrate a wafer during various steps of a processing method to form a variable thickness layer over a backside of the wafer in accordance with an embodiment of this disclosure;

FIG. 4A-4C illustrate a wafer during various steps of a processing method to form a variable thickness layer over a backside of the wafer in accordance with an embodiment of this disclosure;

FIGS. 5A-5B illustrate shapes which may be used in the processing method to form a variable thickness layer on a backside of a wafer as described using FIGS. 4A-4C in accordance with an embodiment of this disclosure;

FIGS. 6A-6B are schematic diagrams of a wafer bonding system capable of implementing the wafer bonding method of FIGS. 1A-1J in accordance with an embodiment of this disclosure;

FIG. 7 illustrates a schematic diagram of a first wafer holder and a second wafer holder which may be used in the wafer bonding system of FIGS. 6A-6B in accordance with an embodiment of this disclosure;

FIG. 8 illustrates a wafer comprising a variable thickness layer during various steps of a method of loading the wafer on a wafer holder such that the variable thickness layer contacts the wafer holder in accordance with an embodiment of this disclosure;

FIG. 9 is a flowchart illustrating a wafer bonding method in accordance with an embodiment of this disclosure; and

FIG. 10 is a flowchart illustrating a wafer bonding method in accordance with another embodiment of this disclosure.

### DETAILED DESCRIPTION OF ILLUSTRATIVE EMBODIMENTS

During wafer-to-wafer bonding processes, significant wafer scaling effects occur as one wafer stretches to overcome the gap between two wafers, resulting in dilation (or scaling) of one wafer of the two wafers. Current manufacturing specifications target total bonding misalignment of less than 30 nm, making this scaling effect a challenge. While existing flexible chuck systems attempt to address this scaling, they typically introduce several micrometers of shape variation across the wafer, creating non-uniform distortions. These non-uniform distortions are difficult to correct using conventional methods.

This disclosure uses a variable thickness layer formed on a backside of a wafer and a wafer bonding system comprising substantially planar (or flat) wafer holders, rather than using flexible chuck systems. By utilizing a highly flat rigid chuck as the wafer holder and forming a variable thickness layer over a backside of one of the wafers, the wafer bonding system can achieve controlled wafer scaling compensation during the bonding process. The variable thickness layer can be precisely formed through various methods, such as controlled deposition processes, exposure processes, removal of unexposed film, multi-patterning, or combinations thereof. Unlike traditional flexible chuck approaches, this method enables more uniform and predictable wafer shaping when the wafer comprising the variable thickness layer is chucked (or loaded) on the wafer holder. The variable thickness layer can be removed after bonding is complete, leaving the wafers precisely aligned without the non-uniform distortions typically associated with flexible chuck systems.

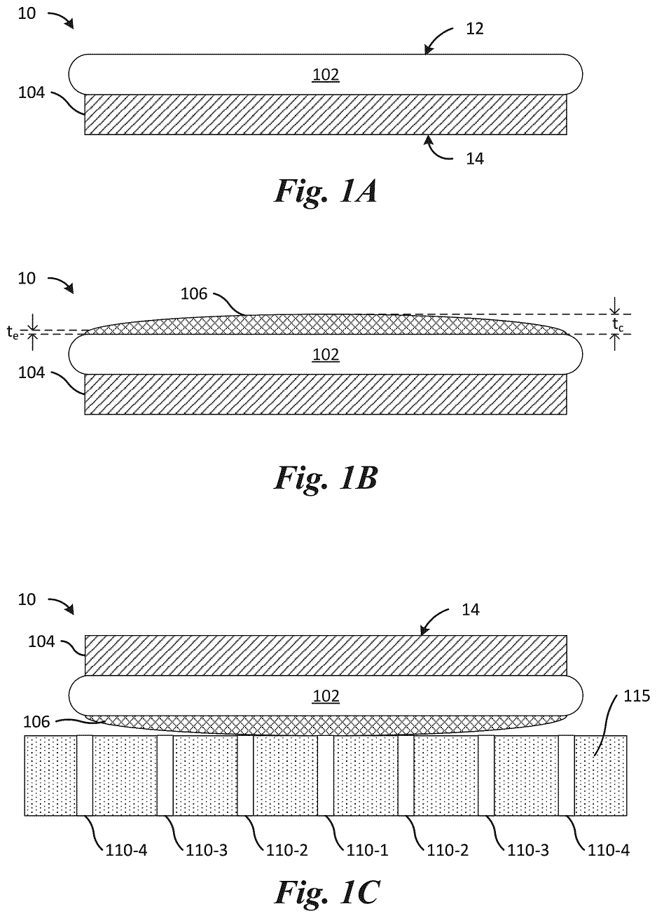

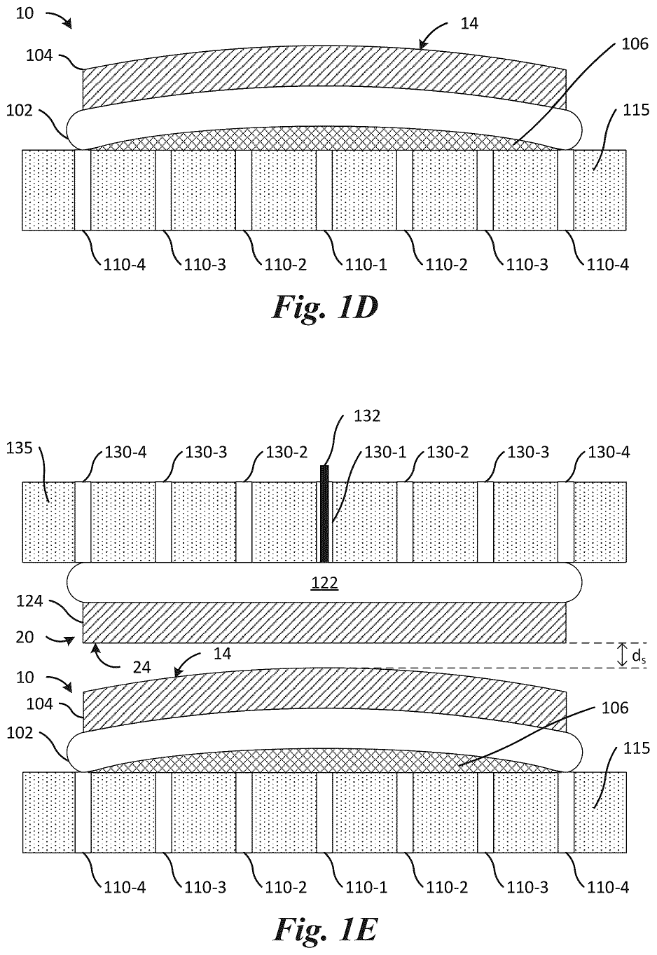

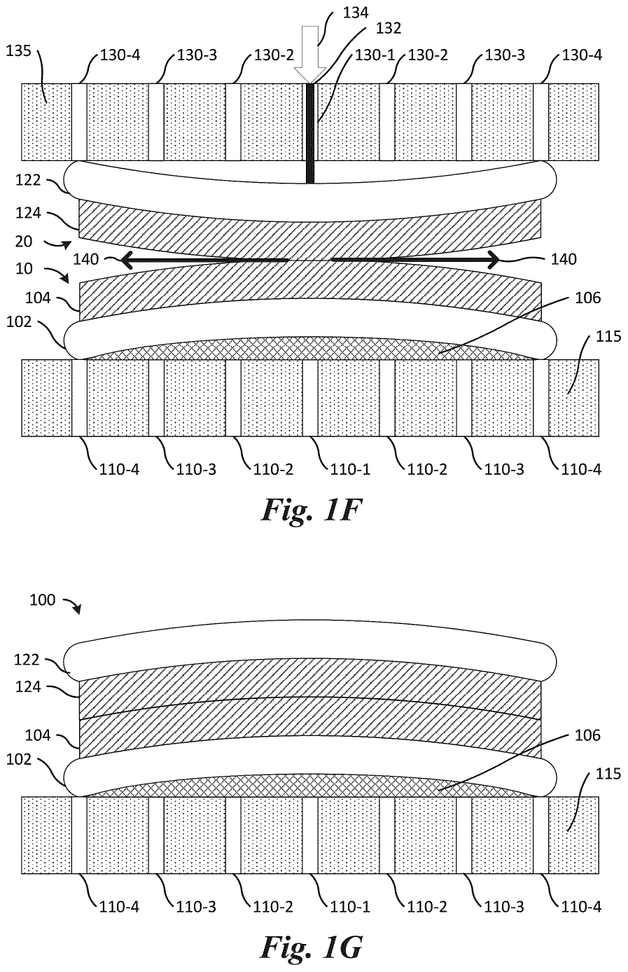

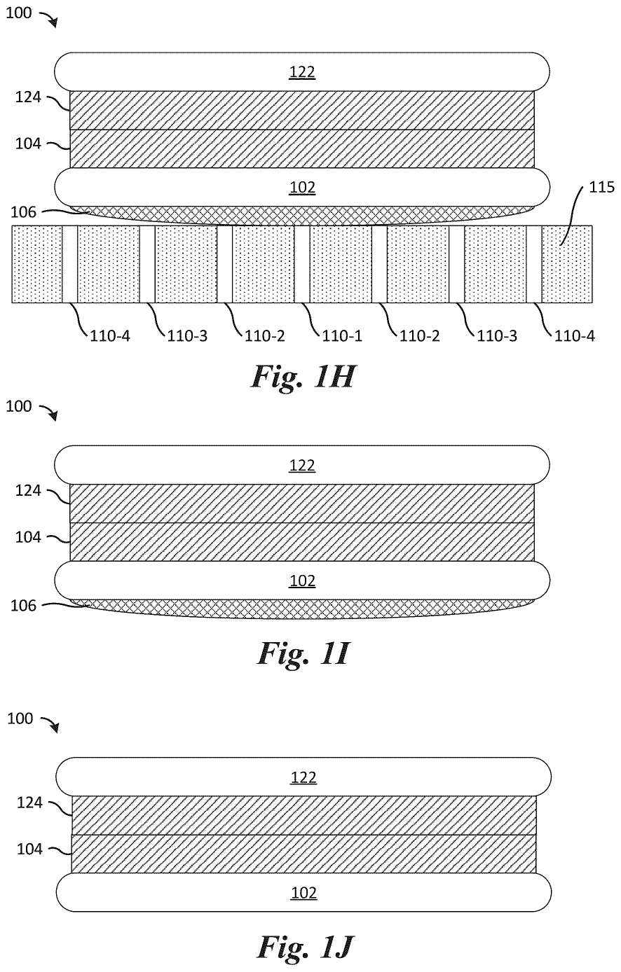

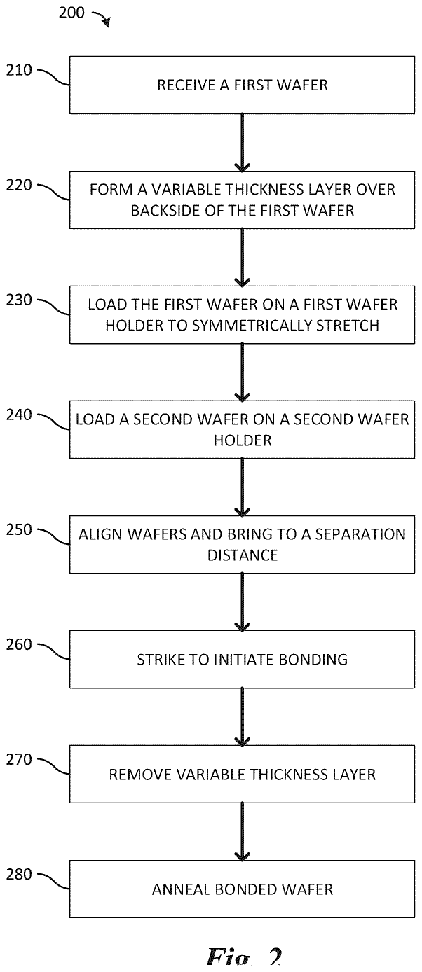

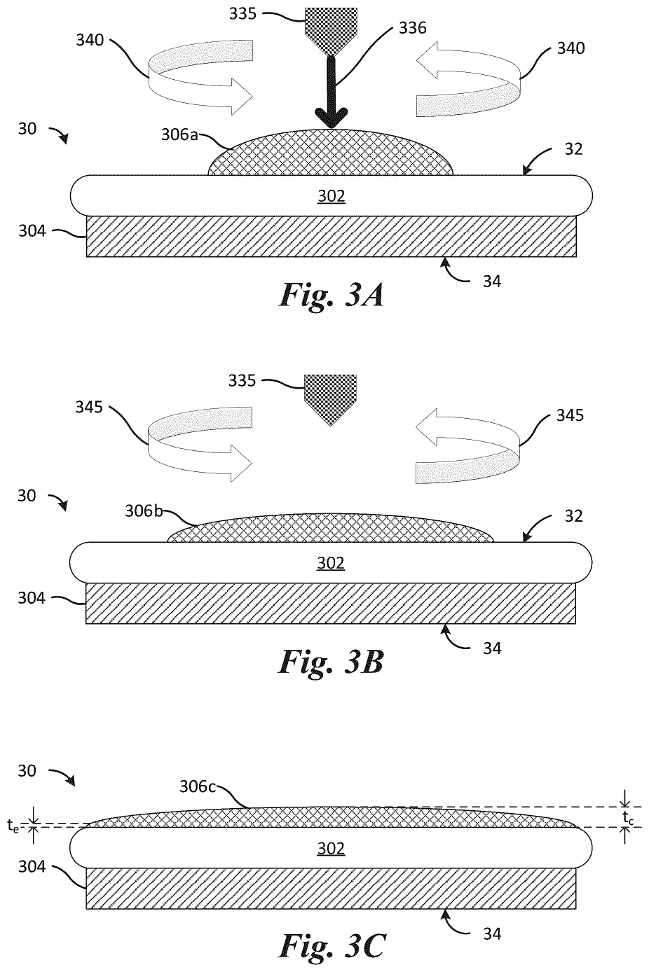

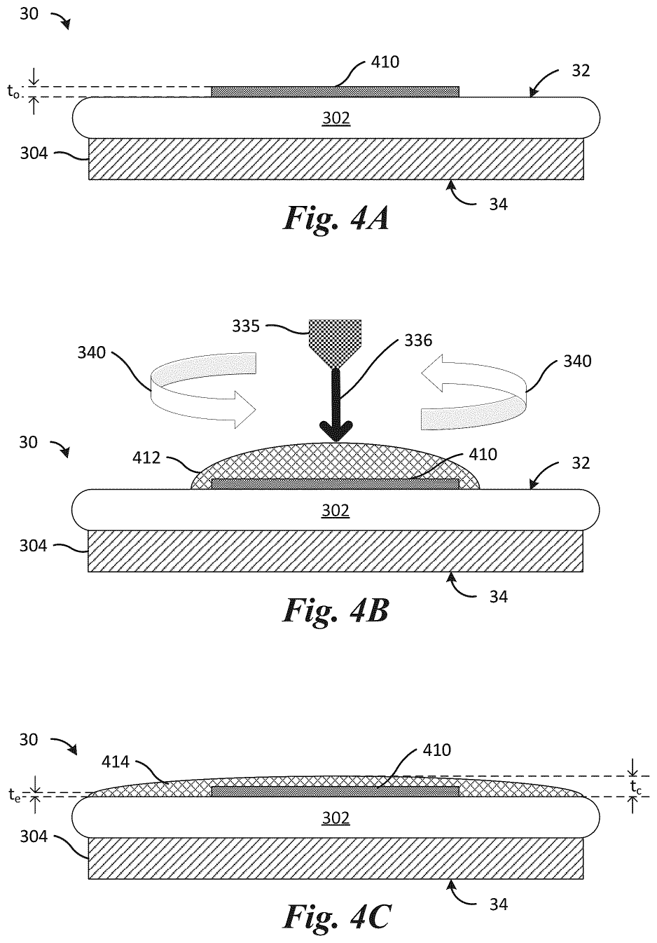

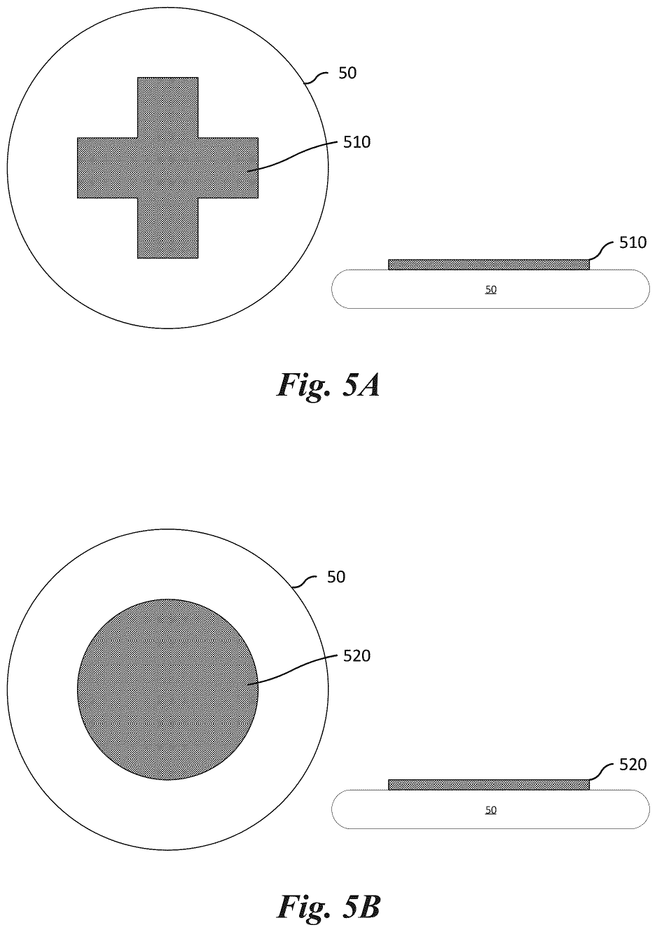

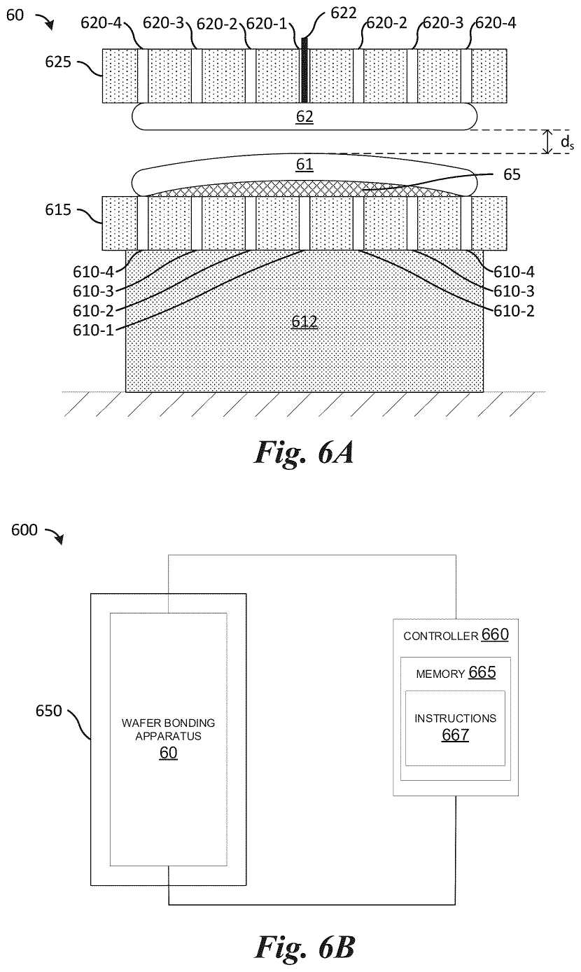

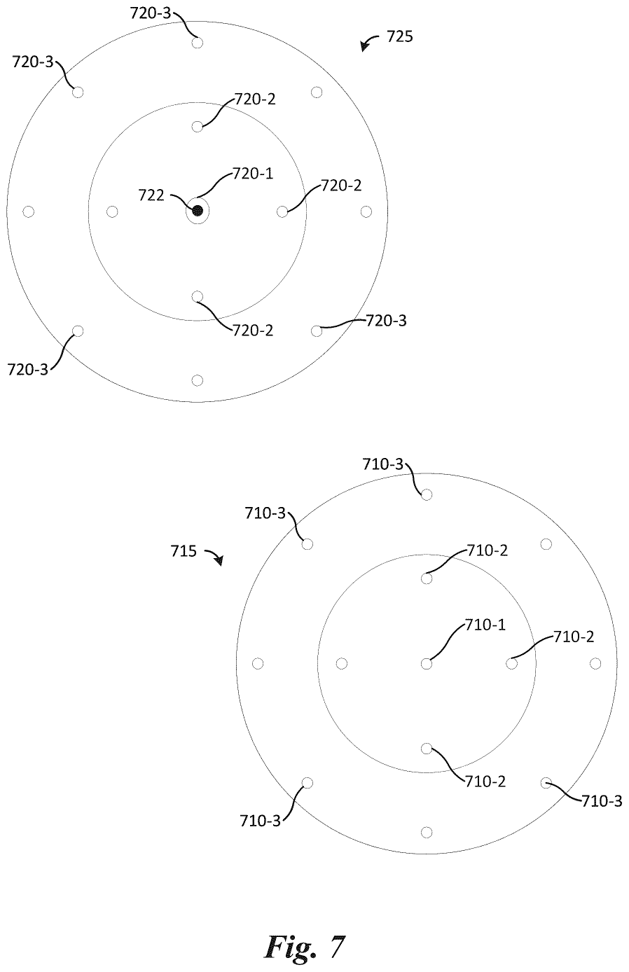

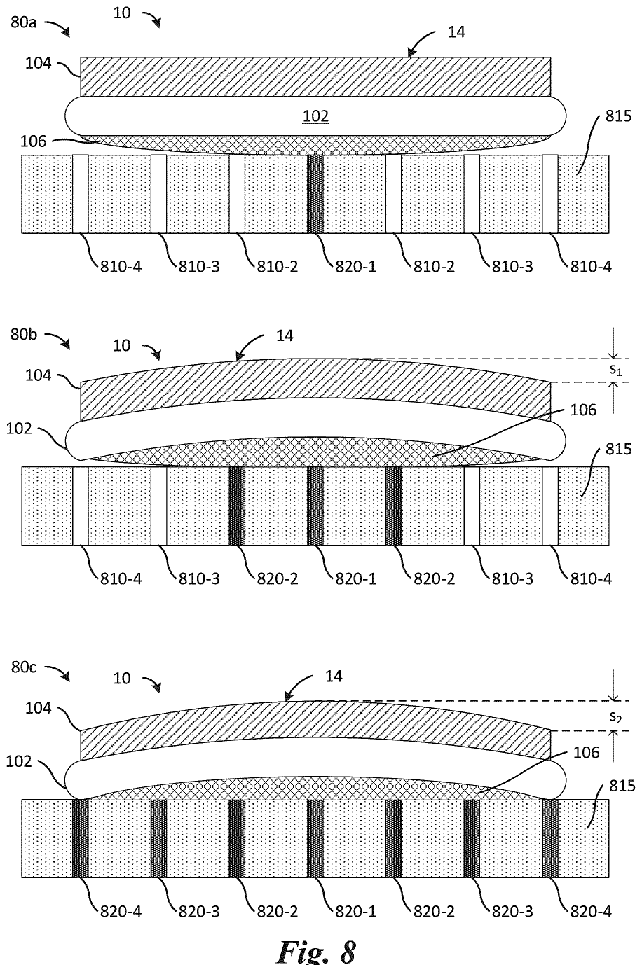

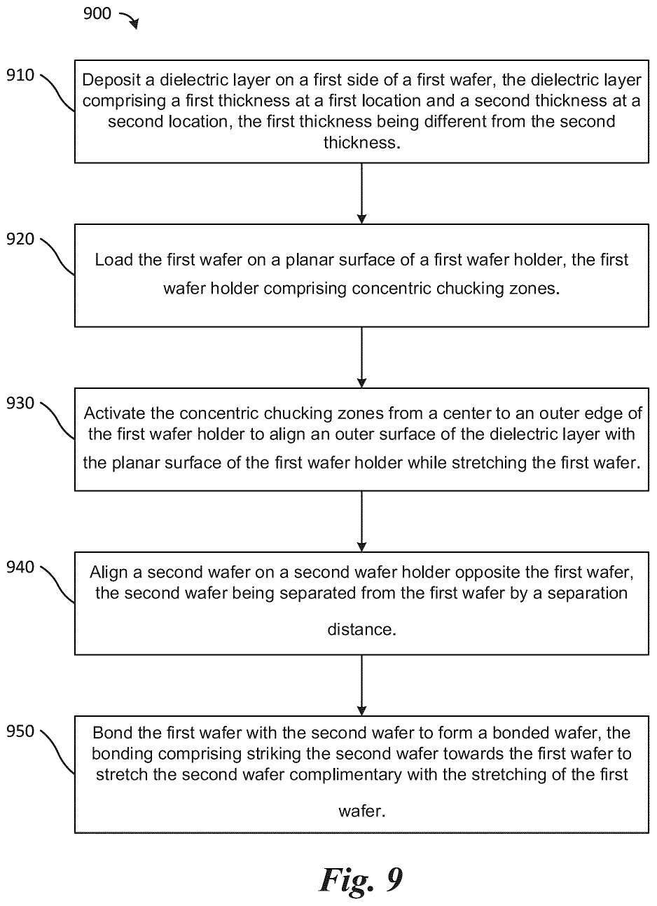

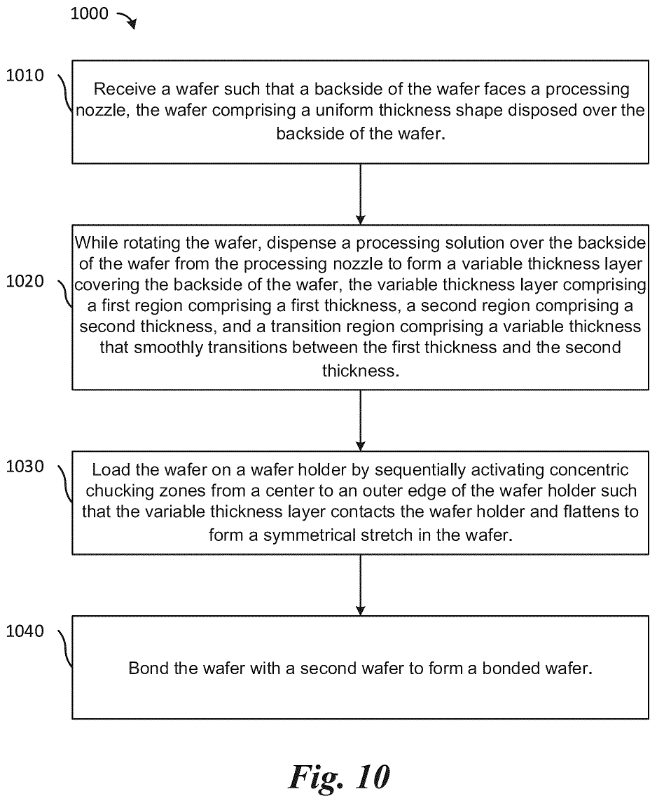

Embodiments provided below describe various methods for bonding wafers, and in particular embodiments, to methods of bonding wafers using a variable thickness layer to mitigate scaling. The following description describes the embodiments. FIGS. 1A-1J describe an example wafer bonding method for forming a bonded wafer using a variable thickness layer to mitigate scaling. FIG. 2 is a flowchart which may be used to describe an embodiment wafer bonding method that uses a variable thickness layer, such as the wafer bonding method illustrated in FIGS. 1A-1J. FIGS. 3A-3C describe an embodiment method of forming a variable thickness layer over a backside of a wafer. Similarly, FIGS. 4A-4C describe another embodiment method of forming a variable thickness layer over a backside of a wafer. Various shapes which may be used in the forming of a variable thickness layer according to the embodiment method of FIGS. 4A-4C are illustrated in FIGS. 5A-5B. A wafer bonding system comprising a wafer bonding apparatus capable of implementing the wafer bonding method of this disclosure is described using FIGS. 6A-6B. FIG. 7 illustrates an embodiment first wafer holder and second wafer holder which may be used in a wafer bonding apparatus to bond wafers where one wafer comprises a variable thickness layer, such as the wafer bonding apparatus of FIG. 6A. A method of loading (or chucking) a wafer comprising a variable thickness layer such that a symmetrical stretch (or dilation) is formed in the wafer is described using FIG. 8. And the flowcharts of FIGS. 9-10 illustrate example methods of forming a bonded wafer using a variable thickness layer to mitigate scaling in accordance with embodiments of this disclosure.

FIGS. 1A-1J illustrate cross-sectional views of wafers during various steps of a wafer bonding method of this disclosure. In the wafer bonding method illustrated in FIGS. 1A-1J, a variable thickness layer is formed on one of the wafers to be bonded, which may be used to cause a symmetrical stretch in the wafer which correlates with a complimentary stretch formed in the other wafer during striking in the bonding process such that both wafers comprise the same symmetrical stretch (or dilation factor) after bonding. The steps of the wafer bonding method of this disclosure may be incorporated into various conventional bonding processes, such as direct bonding, adhesive bonding, and fusion bonding.

Now referring to FIG. 1A, the wafer bonding method of this disclosure may start by receiving a first wafer 10 in a suitable processing chamber for forming a variable thickness layer. The first wafer 10 may be received such that the variable thickness layer may be formed over a backside 12 of the first wafer 10. Further, the first wafer 10 may be received such that a topside 14 of the first wafer 10 contacts a wafer holder of the suitable processing chamber to form the variable thickness layer over the backside 12, such as a spin-coater chamber, a chemical vapor deposition (CVD) chamber, a plasma-enhanced CVD (PECVD), an atomic layer deposition (ALD) chamber, or other chambers suitable for forming a layer comprising a desired thickness gradient. As illustrated in FIG. 1A, the first wafer 10 comprises the backside 12, the topside 14, a first substrate 102, and first layers 104. In various embodiments, the backside 12 may be a first side of the first wafer 10 and the topside 14 may be a second side of the first wafer 10.

In one or more embodiments, the first substrate 102 may be a silicon wafer, or a silicon-on-insulator (SOI) wafer. In certain embodiments, the first substrate 102 may comprise a silicon germanium wafer, silicon carbide wafer, gallium arsenide wafer, gallium nitride wafer and other compound semiconductors. In other embodiments, the first substrate 102 comprises heterogeneous layers such as silicon germanium on silicon, gallium nitride on silicon, silicon carbon on silicon, as well as layers of silicon on a silicon or SOI substrate. In various embodiments, the first substrate 102 may be a component of, or comprise, a semiconductor device (e.g., a transistor), and may have undergone a number of processing steps following, for example, a conventional process recipe. For example, the first wafer 10 may comprise the first substrate 102 in which various device regions are formed.

In various embodiments, the first layers 104 may comprise various metallization layers, dielectric layers, device layers of a device being fabricated, and a bonding layer for bonding the first wafer 10 with another wafer. Further, the first layers 104 may be formed using a conventional process using suitable deposition, patterning, and etching techniques to form the first layers 104. In various embodiments, the first layers 104 may comprise a dielectric material. In certain embodiments, the first layers 104 may comprise a silicon oxide layer. In alternate embodiments, the first layers 104 may comprise silicon nitride, silicon oxynitride, or an O/N/O/N layer stack (stacked layers of oxide and nitride). The first layers 104 may be deposited using an appropriate technique such as vapor deposition including chemical vapor deposition (CVD), physical vapor deposition (PVD), atomic layer deposition (ALD), as well as other plasma processes such as plasma enhanced CVD (PECVD) and other processes. In one embodiment, the first layers 104 have a thickness between 1 μm and 10 μm. In another embodiment, the first layers 104 may comprise a back end of line (BEOL) layer disposed over a front end of line (FEOL) layer.

In one or more embodiments, the first layers 104 may comprise a bonding layer formed from any suitable bonding material deposited through a deposition process. For example, in various embodiments, a bonding layer of the first layers 104 may comprise tetraethyl orthosilicate (TEOS), silicon oxide, silicon nitride, silicon oxynitride, polymers, organic adhesive layers, or glass.

FIG. 1B illustrates a cross-sectional view of the first wafer 10 after forming a variable thickness layer 106 over the backside 12. The variable thickness layer 106 may be formed through any suitable method for forming a layer with a varying thickness or a thickness gradient. In one or more embodiments, the variable thickness layer 106 may comprise a flexible material which may be flattened or stretched when the first wafer 10 is loaded on a wafer holder. In an embodiment, the variable thickness layer 106 may comprise a dielectric material. In various embodiments, the variable thickness layer 106 may comprise polydimethylsiloxane (PDMS), polyurethane, epoxy resins, photoresists, or acrylic polymers. In one or more embodiments, the variable thickness layer 106 may be a dielectric layer formed comprising a first thickness at a first location and a second thickness at a second location, where the first thickness is different than the second thickness.

In an embodiment, the variable thickness layer 106 may be formed using a spin-coater configured to emit a processing solution at a flow rate while rotating the first wafer 10 at a rotation speed. In an embodiment using the spin-coater, the rotation speed of the first wafer 10 may be slow enough to form the variable thickness layer 106. In another embodiment, an object layer, such as a dielectric layer, may be formed on the backside 12 of the first wafer 10 and subsequently coated with another material to form the variable thickness layer 106 comprising a bump or a smooth step height change between a first region comprising the object layer and a first thickness and a second region comprising the outer edge of the first wafer 10 and a second thickness. In similar embodiments, a multi-patterning process comprising deposition, exposure, and etching steps may be performed to form a stepped structure which may be subsequently coated with another material to form the variable thickness layer 106 comprising a smooth step height change (or a thickness gradient between a first region and a second region). Further methods of forming the variable thickness layer 106 on the backside 12 of the first wafer 10 may be described using FIGS. 3A-3C and FIGS. 4A-4C below.

The variable thickness layer 106 comprises an edge thickness (tₑ) and a center thickness (t_{c}). In various embodiments, the center thickness (t_{c}) may be larger than the edge thickness (tₑ). Further, the center thickness (t_{c}) may vary between 1 μm and 200 μm, and the edge thickness (tₑ) may vary between 100 nm and 20 μm as may be desired. In one or more embodiments, the variable thickness layer 106 may be a high-viscosity material suitable for forming the variable thickness layer 106 by spinning the first wafer 10 at a slow rotation speed. A center region of the variable thickness layer 106 may be a first region at a first thickness, where the first thickness is the center thickness (t_{c}). An edge region of the variable thickness layer 106 may be a second region at a second thickness, where the second thickness is the edge thickness (tₑ). And the variable thickness layer 106 comprises a transition region which comprises a thickness gradient to smoothly transition in step height between the center thickness (t_{c}) and the edge thickness (tₑ). In other embodiments, the transition in step height between the center thickness (t_{c}) and the edge thickness (tₑ) may be abrupt. In multiple embodiments, the center region may be a first location, where the center thickness (t_{c}) is a first thickness. Similarly, in those same embodiments, the edge region may be a second location, where the edge thickness (tₑ) is a second thickness.

FIG. 1C illustrates the first wafer 10 loaded on a first wafer holder 115 as the first wafer 10 may be received after forming the variable thickness layer 106. In various embodiments, the first wafer holder 115 may be a part of a wafer bonding apparatus configured to bond the first wafer 10 with another wafer. The first wafer holder 115 comprises a first vacuum nozzle 110-1 disposed in a center of the first wafer holder 115, a plurality of second vacuum nozzles 110-2 disposed around the first vacuum nozzle 110-1, a plurality of third vacuum nozzles 110-3 disposed around the first vacuum nozzle 110-1 at a larger radial distance than the plurality of second vacuum nozzles 110-2, and a plurality of fourth vacuum nozzles 110-4 disposed around the fist vacuum nozzle 110-1 at an even larger radial distance than the plurality of third vacuum nozzles 110-3. The first wafer holder 115 comprises concentric chucking zones, where each of the concentric chucking zones comprises a set of the various vacuum nozzles (110-1-110-4). Other embodiments may use more or less of the various vacuum nozzles (110-1-110-4) and may use different diameters.

The first wafer holder 115 is substantially planar (or flat) such that a center region of the variable thickness layer 106 contacts the first vacuum nozzle 110-1 when initially loaded, but an edge region remains floating. In other words, the first wafer holder 115 comprises a planar surface configured to hold the first wafer 10 during bonding. In one or more embodiments, the first wafer holder 115 comprises a vacuum chuck, and the various vacuum nozzles (110-1-110-4) comprise various vacuum nozzles configured to hold the first wafer 10 by using a vacuum. Further, the various vacuum nozzles (110-1-110-4) may be configured such that each is independently controllable, which may enable a chucking sequence (or loading sequence) where the various vacuum nozzles (110-1-110-4) may be sequentially activated as desired to bring the entirety of the variable thickness layer 106 into contact with the first wafer holder 115.

FIG. 1D illustrates the first wafer 10 after activating the first wafer holder 115 such that the variable thickness layer 106 of the first wafer 10 stretches the first wafer 10 to form a symmetrical stretch as desired according to the thickness gradient of the variable thickness layer 106. The symmetrical stretch of the first wafer 10 may be formed by activating the various vacuum nozzles (110-1-110-4) of the first wafer holder 115 in a suitable manner. In various embodiments, the symmetrical stretch of the first wafer 10 may be formed by first activating the first vacuum nozzle 110-1, and subsequently activating the remaining vacuum nozzles (110-2 110-4) from the center to the edge of the first wafer 10 to systematically pull the variable thickness layer 106 into contact with the first wafer holder 115. After chucking the first wafer 10 in the first wafer holder 115, the wafer bonding method may proceed to load and align another wafer to be bonded with the first wafer 10.

FIG. 1E illustrates the first wafer 10 and a second wafer 20 in a wafer bonding apparatus after loading and aligning the second wafer 20 on a second wafer holder 135 disposed over the first wafer 10. Additionally, the second wafer 20 has been brought to a separation distance (dₛ) suitable for initiating bonding between the first wafer 10 and the second wafer 20.

The second wafer 20 comprises second layers 124 disposed over a second substrate 122. Further, the second wafer 20 may be loaded on the second wafer holder 135 such that the second substrate 122 contacts the second wafer holder 135. In various embodiments, the second layers 124 may be as described for the first layers 104, and the second substrate 122 may be as described for the first substrate 102.

In the embodiment illustrated in FIG. 1E, the second wafer holder 135 is a vacuum chuck that is substantially flat. The second wafer holder 135 comprises various vacuum nozzles (130-1-130-4), which may be similar to the various vacuum nozzles (110-1-110-4) of the first wafer holder 115. In one or more embodiments, the second wafer holder 135 comprises a first vacuum nozzle 130-1 disposed in a center of the second wafer holder 135, a plurality of second vacuum nozzles 130-2 disposed around the first vacuum nozzle 130-1, a plurality of third vacuum nozzles 130-3 disposed around the first vacuum nozzle 130-1 at a larger radial distance than the plurality of second vacuum nozzles 130-2, and a plurality of fourth vacuum nozzles 130-4 disposed around the first vacuum nozzle 130-1 at an even larger radial distance than the plurality of third vacuum nozzles 130-3. The second wafer holder 135 further comprises a striker 132 disposed in the first vacuum nozzle 130-1, which may enable the striker 132 to strike a center of a backside of the second wafer 20 to initiate bonding between the first wafer 10 and the second wafer 20. Embodiments of the first wafer holder 115 and the second wafer holder 135 are described further using FIG. 7.

In various embodiments, the separation distance (dₛ) may be comparable to the center thickness of the variable thickness layer 106 such that a complimentary stretch may be formed in the second wafer 20 once struck by the striker 132 to initiate bonding. In those embodiments, the separation distance (dₛ) may vary between 1 μm and 200 μm.

FIG. 1F illustrates the first wafer 10 and the second wafer 20 in the wafer bonding apparatus after striking 134 the second wafer 20 with the striker 132 to initiate bonding and start a bond front 140 propagating. The bond front 140 may propagate from a center of the first wafer 10 and the second wafer 20 to outer edges of the first wafer 10 and the second wafer 20. During the bond front 140 propagation, the various vacuum nozzles (130-1-130-4) of the second wafer holder 135 may be systematically controlled to advantageously release the second wafer 20 to adjust a propagation speed of the bond front 140. For example, the various vacuum nozzles (130-1-130-4) may be controlled to increase or decrease the propagation rate of the bond front 140 as desired.

The striker 132 closes the separation distance (dₛ) between the first wafer 10 and the second wafer 20 by striking 134 the second wafer 20 into the first wafer 10. Consequently, a symmetrical stretch (or a complimentary stretch) may be formed in the second wafer 20 that mirrors the symmetrical stretch of the first wafer 10 formed by the flattening (or chucking) of the variable thickness layer 106. In various embodiments, the symmetrical stretch of the second wafer 20 may be a complimentary stretch, or a dilation of the second wafer 20. And in similar embodiments, the symmetrical stretch of the first wafer 10 may be a dilation of the first wafer 10. During the propagation of the bond front 140, the first wafer 10 remains chucked or loaded on the first wafer holder 115 to maintain the symmetrical stretch of the first wafer 10.

FIG. 1G illustrates a bonded wafer 100 formed after striking the second wafer 20 into the first wafer 10 and the bond front 140 fully propagating from the center of the topside 14 of the first wafer 10 to the edges. As illustrated, both the first wafer 10 and the second wafer 20 comprise the same symmetrical stretch or dilation which enables the bonded wafer 100 to be formed comprising scaling factors within 6 ppm, and desired alignment of device elements between the first layers 104 and the second layers 124 within a tolerance of less than 30 nm misalignment.

After forming the bonded wafer 100, the wafer bonding method may proceed to release the variable thickness layer 106 from the first wafer holder 115. In various embodiments, the release of the variable thickness layer 106 from the first wafer holder 115 may comprise the steps of the loading (or chucking) sequence, but in reverse.

FIG. 1H illustrates the bonded wafer 100 after releasing the various vacuum nozzles (110-1-110-4) of the first wafer holder 115 such that the variable thickness layer 106 is no longer pulled into contact with the first wafer holder 115. The bonded wafer 100 may relax to an undistorted (or planar) shape after the release of the variable thickness layer 106, but the dilation (or symmetrical stretch) of the bonded wafer 100 remains. For example, both the first wafer 10 and the second wafer 20 may be dilated to a larger size such that the bonded wafer 100 comprises the larger size (dilation) without the warped shape from the flattening caused by the chucking of the variable thickness layer 106 to the first wafer holder 10.

FIG. 1I illustrates the bonded wafer 100 after being removed from the first wafer holder 115 of the wafer bonding apparatus. After removing the bonded wafer 100 from the wafer bonding apparatus, the bonded wafer 100 may be loaded in a suitable processing tool capable of removing the variable thickness layer 106.

In various embodiments, after dechucking the bonded wafer 100 in FIG. 1I, the wafer bonding method may proceed to further processing steps to finish forming the device. For example, the wafer bonding method may proceed to remove the variable thickness layer 106 from the bonded wafer 100, such as described using FIG. 1J below.

FIG. 1J illustrates the bonded wafer 100 after removing the variable thickness layer 106. The bonded wafer 100 comprises the first wafer 10 bonded to the second wafer 20 without scaling, which results from the use of the variable thickness layer 106 to form the symmetrical stretch in the first wafer 10. In various embodiments, the variable thickness layer 106 may be removed through a chemical-mechanical planarization (CMP) process. In other embodiments, an etch process may be used to remove the variable thickness layer 106, such as a wet-etch process or a dry-etch process. For example, the variable thickness layer 106 may be removed by exposing the variable thickness layer to a plasma, or by using a reactive ion etching (RIE) process. In various embodiments, the bonded wafer 100 may be further processed after removing the variable thickness layer 106. For example, in one or more embodiments, the bonded wafer 100 may be annealed to improve bond strength and finish forming the bonded wafer 100. In other embodiments, an annealing step may be performed before removing the variable thickness layer 106.

FIG. 2 is a flowchart illustrating various steps of a wafer bonding method 200. For example, the wafer bonding method 200 may be used to describe the various steps of the wafer bonding method illustrated using FIGS. 1A-1J in an embodiment. In one or more embodiments, the wafer bonding method 200 may start by receiving a first wafer in step 210. The first wafer may be the first wafer 10, and step 210 may be illustrated by FIG. 1A. The first wafer may have undergone various processing steps prior to being received in step 210 to prepare the first wafer to have a layer deposited over a backside of the first wafer. As an example, the first wafer may be received and loaded on a wafer holder of a spin coater to form a layer over a backside of the first wafer.

After receiving the first wafer in step 210, the wafer bonding method 200 may proceed to step 220. In step 220, the wafer bonding method 200 forms a variable thickness layer over a backside of the first wafer. The variable thickness layer may be formed over the backside of the first wafer through a suitable method, such as by using a spin-coater. Additionally, the variable thickness layer may be formed such that a center thickness of the variable thickness layer is larger than an edge thickness of the variable thickness layer. In an embodiment, step 220 of the wafer bonding method 200 may be illustrated by the variable thickness layer 106 formed over the backside 12 of the first wafer 10 in FIG. 1B.

In step 230, the wafer bonding method 200 loads the first wafer on a first wafer holder to symmetrically stretch the first wafer. The first wafer may be loaded such that the variable thickness layer contacts the first wafer holder. Various concentric chucking zones of the first wafer may be sequentially activated to pull and flatten the entirety of the variable thickness layer into contact with the first wafer holder, the first wafer holder being substantially flat. As a result, a symmetrical stretch may be formed in the first wafer where the symmetrical stretch dilates the first wafer. In various embodiments, the first wafer holder may be the first wafer holder 115, the various concentric chucking zones may be the various vacuum nozzles (110-1 110-4) of FIG. 1C, and the loading of the first wafer on the first wafer holder may be illustrated by the steps shown in FIG. 1C and FIG. 1D. In other embodiments, step 230 of the wafer bonding method 200 may be illustrated by the loading process described using FIG. 8 below.

Still referring to FIG. 2, in step 240, the wafer bonding method 200 loads a second wafer on a second wafer holder. In various embodiments, the second wafer may be the second wafer 20 and the second wafer holder may be the second wafer holder 135 of FIG. 1E. And in step 250, the wafer bonding method 200 aligns the first wafer and the second wafer and brings the first wafer and the second wafer to a separation distance as may be desired. In similar embodiments, step 240 and step 250 may be illustrated by FIG. 1E, and the separation distance may be the separation distance (dₛ). The separation distance may be determined such that a complimentary stretch that is approximately the same as the symmetrical stretch of the first wafer is formed in the second wafer when struck into the first wafer.

Step 260 of the wafer bonding method 200 strikes to initiate bonding of the first wafer with the second wafer. Step 260 may be the step shown in FIG. 1F, where the striker 132 is used to strike the second wafer 20 into the first wafer 10, and the strike of step 260 is the striking 134 of FIG. 1F.

In one or more embodiments, a thickness gradient of the variable thickness layer and the thicknesses of the center thickness and the edge thickness (the different thickness of the different regions of the variable thickness layer) may be predetermined and subsequently formed based on the separation distance and the release sequence of the second wafer from the second wafer holder. In those embodiments, the thickness gradient may be determined such that the symmetrical stretch of the first wafer forms the same scaling (or dilation) in the first wafer as the complimentary stretch forms in the second wafer by the striking and releasing of the second wafer into the first wafer from the second wafer holder.

After bonding the first wafer and the second wafer to form a bonded wafer in step 260, the wafer bonding method may proceed to step 270. In step 270, the wafer bonding method 200 removes the variable thickness layer from the first wafer of the bonded wafer, which may be done through a suitable processing method such as an etch process or as described for FIG. 1J above. And in step 280, the wafer bonding method 200 anneals the bonded wafer. In other embodiments, step 280 may be performed after step 260, and step 270 may be performed after step 280. A processing method which may be used in step 220 to form the variable thickness layer on the backside of the first wafer is described using FIGS. 3A-3C below.

FIGS. 3A-3C illustrate cross-sectional views of a wafer 30 during various steps of an embodiment processing method to form a variable thickness layer over a backside 32 of the wafer 30. The wafer 30 comprises a substrate 302 and layers 304. The wafer 30 further comprises a topside 34 and a backside 32. The wafer 30 may be as previously described for the first wafer 10, and the elements of the wafer 30 may be as similarly described for the elements of the first wafer 10 as well. For example, the substrate 302 may be as described for the first substrate 102 of the first wafer 10 and the layers 304 may be as described for the first layers 104 of the first wafer 10.

Now referring to FIG. 3A, in an embodiment, the wafer 30 may be received in a spin-coater comprising a fluid nozzle 335 configured to flow 336 a processing solution over the backside 32 of the wafer 30 while rotating 340 the wafer 30 at a first rotation rate. In FIG. 3A, the flow 336 deposits a first layer 306a over the backside 32 of the wafer 30.

In FIG. 3B, the rotating 340 may spread the first layer 306a into a second layer 306b which covers a larger area of the backside 32 of the wafer 30. Additionally, the flow 336 may be stopped in FIG. 3B such that a desired quantity of processing solution may be further spun to the edges of the wafer 30. Other embodiments may maintain the flow 336 throughout the processing method for forming a variable thickness layer, but may alter the flow rate as desired. After, the first rotation rate may be accelerated to a second rotation rate as desired in a second rotating 345 to spread the second layer 306b to the edges of the wafer 30.

Now referring to FIG. 3C, the processing method may stop the second rotating 345 once the second layer 306b has spread as desired to form a variable thickness layer 306c comprising an edge thickness (tₑ) and a center thickness (t_{c}). In one or more embodiments, the center thickness may be larger than the edge thickness, such that the edges of the wafer 30 may be pulled down (or flattened) by the chucking of the wafer 30 in a suitable wafer holder of a wafer bonding apparatus. In various embodiments, different rotation rates may be used for different processing solutions depending on the viscosity and other material properties of the desired material for the variable thickness layer 306c. Other embodiments may form a variable thickness layer using a multi-patterning process to form a uniform thickness shape over the backside 32 of the wafer 30 before coating to form the variable thickness layer, such as described using FIGS. 4A-4C below.

FIGS. 4A-4C illustrate cross-sectional views of the wafer 30 during various steps of another embodiment processing method to form a variable thickness layer over the backside 32 of the wafer 30. The difference between the processing method to form a variable thickness layer over the wafer 30 of FIGS. 4A-4C to the processing method of FIGS. 3A-3C is that the processing method of FIGS. 4A-4C form and then coat an object layer 410 to form the variable thickness layer.

Now referring to FIG. 4A, the wafer 30 may be received in a spin-coater after forming the object layer 410 over the backside 32 of the wafer 30. The object layer 410 may be formed over the backside 32 of the wafer 30 through a suitable patterning process prior to receiving the wafer 30 in the spin-coater. Further, the object layer 410 may comprise a dielectric material, or a photoresist, or other conventional materials used in semiconductor manufacturing.

In various embodiments, the object layer 410 may be formed through a conventional multi-patterning technique comprising various conventional steps, such as a deposition, exposure, and etching process. For example, in those embodiments, the deposition may comprise depositing a material over the backside 32 of the wafer 30 through spin-coating, chemical vapor deposition (CVD), plasma-enhanced CVD (PECVD), atomic layer deposition (ALD), or other deposition methods. Additionally, the exposure may comprise a gas development process, or a lithography process. And the etching may be performed through a suitable etch process, such as by using a capacitively coupled plasma (CCP), an inductively coupled plasma (ICP), a reactive ion etching (RIE), or a wet-etching process. In one or more embodiments, the object layer 410 may comprise a shape and an object thickness (tₒ), where the object thickness (tₒ) may be a uniform thickness across the object layer 410 between 1 μm and 200 μm.

The shape of the object layer 410 may be a desired shape for forming a symmetrical stretch in the wafer 30 (once flattened by the chucking process) that mitigates scaling between wafers. In one or more embodiments, the shape of the object layer 410 may be a cross, a polygon, or an ellipse. Example shapes of the object layer 410 are described further using FIGS. 5A-5B below. In some embodiments, the object layer 410 may comprise a stepped structure comprising multiple object layers formed through similar techniques as described above, such as through multiple multi-patterning techniques.

FIG. 4B performs the same step as described in FIG. 3A, but with the wafer 30 comprising the object layer 410, and the fluid nozzle 335 configured to flow 336 a processing solution 412 over the object layer 410 while rotating 340 the wafer 30 at a predetermined (or preconfigured) rotation rate. The processing solution 412 may be a suitably viscous material capable of dispensing from the fluid nozzle 335 and spreading across the backside 32 of the wafer 30 to form a variable thickness layer, such as polydimethylsiloxane (PDMS), polyurethane, epoxy resins, photoresists, or acrylic polymers.

Now referring to FIG. 4C, the wafer 30 may have been rotated such that the processing solution 412 spread and formed a variable thickness layer 414 over the object layer 410. The variable thickness layer 414 comprises an edge thickness (tₑ) and a center thickness (t_{c}), and a transition region that bridges the two thicknesses. The transition region between the center thickness (t_{c}) and the edge thickness (tₑ) comprises a thickness gradient. The thickness gradient enables a smooth step height change between the thicknesses of a center region (first region) and an edge region (second region) of the wafer 30.

FIGS. 5A-5B illustrate top views and cross-sectional views of shapes which may be used in the processing method to form a variable thickness layer on a backside of a wafer 50 such as described using FIGS. 4A-4C. In various embodiments, the wafer 50 may be as described for the first wafer 10, the second wafer 20, or the wafer 30.

Now referring to FIG. 5A, the wafer 50 comprises a first object layer 510 which may be used to form a variable thickness layer in accordance with embodiments of this disclosure. For example, the first object layer 510 may be used as the object layer 410 of FIGS. 4A-4C, and may similarly enable the formation of a variable thickness layer over the backside of the wafer 50. The first object layer 510 may be formed through a conventional multi-patterning process for forming a uniform thickness layer, such as by depositing, exposing, and etching a photoresist or other material. In various embodiments, the first object layer 510 may comprise a photoresist, or a dielectric.

In FIG. 5B, the wafer 50 comprises a second object layer 520 which may be used as similarly described for the first object layer 510 in FIG. 5A. The second object layer 520 comprises a circular shape which may be formed similarly to the first object layer 510, but the second object layer 520 may form a different thickness gradient (or topological profile) in the variable thickness layer once coated. In further embodiments, other object layers may be a stepped structure comprising multiple object layers stacked to enable a smoother step height (or thickness gradient) in a variable thickness layer formed on a backside of the wafer 50. In those other embodiments, the stepped structure may be formed through multiple multi-patterning processes. Various uniform thickness shapes may be used for the object layers, such as a polygon, a cross, or an ellipse.

FIGS. 6A-6B are schematic diagrams of a wafer bonding apparatus 60 and a wafer bonding system 600 capable of implementing the wafer bonding method described using FIGS. 1A-1J, or the wafer bonding method 200 of FIG. 2.

FIG. 6A illustrates an embodiment of the wafer bonding apparatus 60 which may be used for the wafer bonding method of this disclosure. The wafer bonding apparatus 60 comprises a first wafer holder 615 disposed on a base 612, and a second wafer holder 625. In various embodiments, wafer bonding apparatus 60 may be operated in a bonding chamber for controlling an environment during use, such as a vacuum chamber or a gas pressurized chamber. A first wafer 61 comprising a variable thickness layer 65 is loaded on the first wafer holder 615, the first wafer holder 61 symmetrically stretched by concentric chucking zones comprising various vacuum nozzles (610-1-610-4). A second wafer 62 is loaded on the second wafer holder 625 using concentric chucking zones comprising various vacuum nozzles (620-1-620-4) of the second wafer holder 625 and brought into alignment within a separation distance (dₛ) of the first wafer 61. The second wafer holder 625 comprises a striker 622 which may be used to initiate bonding of the second wafer 62 with the first wafer 61, the striker 622 forming a complimentary stretch in the second wafer 62 by striking the second wafer 62 to close the gap or separation distance (dₛ).

The base 612 assembly of the wafer bonding apparatus 60 comprises the first wafer holder 615 having a substantially planar upper surface configured to support the first wafer 61. The first wafer holder 615 may be formed from a material having high dimensional stability and minimal thermal expansion characteristics. The upper surface of the first wafer holder 615 comprises concentric chucking zones, such as the vacuum nozzles (610-1-610-4) or vacuum channels arranged in a predetermined pattern to securely hold the first wafer 61 during bonding operations and form the symmetrical stretch (or dilation) in the first wafer 61 by flattening or chucking the variable thickness layer 65 disposed on the backside of the first wafer 61. In various embodiments, the base 612 may comprise a temperature control system configured to maintain a wafer temperature during bonding operations. In further embodiments, the second wafer holder 625 may comprise the same materials as the first wafer holder 615, and may comprise a substantially planar mounting surface configured to hold the second wafer 62 during bonding operations.

In various embodiments, the striker 622 may be as described for the striker 132 in FIGS. 1E-1F. In one or more embodiments, the first wafer 61 and the second wafer 62 may be as described for the first wafer 10 and the second wafer 20 of FIGS. 1A-1J, and the first wafer 61 may be as described for the wafer 30 of FIGS. 3A-3C and 4A-4C. The first wafer holder 615 may be a vacuum chuck, and may be as described for the first wafer holder 115 of FIG. 1C. The second wafer holder 625 may be a vacuum chuck, and may be as described for the second wafer holder 135 of FIG. 1E. Other embodiments of the first wafer holder 615 and the second wafer holder 625 may be described using FIG. 7 below. For example, in alternative embodiments, the first wafer holder 615 may be an electrostatic chuck (ESC) comprising concentric chucking zones which are electrodes, and the second wafer holder 625 may be an electrostatic chuck (ESC) comprising concentric chucking zones which are electrodes. And in further embodiments, one of the wafer holders may be a vacuum chuck while the other is an electrostatic chuck.

FIG. 6B illustrates the wafer bonding system 600 capable of implementing the wafer bonding method described using FIGS. 1A-1J. The wafer bonding system 600 comprises the wafer bonding apparatus 60 of FIG. 6A disposed in a bonding chamber 650, and a controller 660. As illustrated in FIG. 6B, the controller 660 comprises a memory 665 storing instructions 667 to be executed by the controller 660 to operate the wafer bonding apparatus 60. In one or more embodiments, the bonding chamber 650 may be used for controlling an environment during bonding, and the bonding chamber 650 may be a vacuum chamber or a gas pressurized chamber.

The controller 660 may be any device capable of implementing the instructions 667 stored in the memory 665 for controlling and operating the wafer bonding system 600 to implement the wafer bonding method of this disclosure. In the embodiment illustrated in FIG. 6B, the controller 660 is electrically coupled with the wafer bonding apparatus 60 and the bonding chamber 650. The controller 660 may be electrically coupled with the first wafer holder 615, the second wafer holder 625, and the striker 622 to control the positioning, loading, aligning, striking, releasing, and bonding of the first wafer 61 and the second wafer 62. For example, the controller 660 may control the second wafer holder 625 such that the second wafer 62 is brought to the separation distance (dₛ) between the first wafer 61 and the second wafer 62.

The memory 665 may be any device suitable for storing the instructions 667 to be executed by the controller 660, such as instructions for performing the wafer bonding method of FIGS. 1A-1J or the wafer bonding method 200 of FIG. 2. In various embodiments, the memory 665 may comprise RAM, ROM, PROM, EPROM, EEPROM, hard disk, or any other information processing device with which the controller 660 communicates, such as a server or computer. In further embodiments, the wafer bonding system 600 may comprise a detector configured to measure bond front propagation rates throughout the bonding process, such as a light detector. The light detector may be a camera, or other suitable imaging device capable of measuring the bond front propagation rate during the wafer bonding method of this disclosure.

FIG. 7 illustrates a top view schematic diagram of a second wafer holder 725 and a first wafer holder 715 which may be used in the wafer bonding system 600 of FIGS. 6A-6B. In various embodiments, the first wafer holder 715 may be designed to optimize the ability to hold a wafer comprising a variable thickness layer disposed over a backside of the wafer. The second wafer holder 725 and the first wafer holder 715 are an example embodiment, and other embodiments may comprise different elements or parts suitable for performing the wafer bonding method of this disclosure. In the embodiment illustrated in FIG. 7, the second wafer holder 725 and the first wafer holder 715 are vacuum chucks comprising vacuum nozzles for holding wafers during bonding. Additionally, surfaces configured to hold wafers during bonding of the first wafer holder 715 and the second wafer holder 725 are substantially flat or planar to minimize surface variations and dilations in a resulting bonded wafer.

In one or more embodiments, the second wafer holder 725 comprises a first vacuum nozzle 720-1 disposed in a center of the second wafer holder 725, a plurality of second vacuum nozzles 720-2 disposed around the first vacuum nozzle 720-1, and a plurality of third vacuum nozzles 720-3 disposed around the first vacuum nozzle 720-1 at a larger radial distance than the plurality of second vacuum nozzles 720-2. Additionally, the second wafer holder 725 comprises a striker 722 disposed in the center of the second wafer holder 725. The striker 722 may be of any suitable material, and shape for striking to initiate bonding between wafers. Other embodiments may use more than one striker, or the striker may be disposed over an edge of the wafer rather than the center. Various other arrangements and numbers of vacuum nozzles can be used in different embodiments. For example, a number or a size of vacuum nozzles can vary in different embodiments. In some embodiments, different diameters of vacuum nozzles can be used together.

As noted, the operation of the various vacuum nozzles (720-1-720-3) of the second wafer holder 725 can be used for controlling the retention of a wafer during the wafer bonding method of this disclosure (such as the wafer bonding method described using FIGS. 1A-1J, or the wafer bonding method 200 described using FIG. 2). For example, a release sequence involving individual vacuum nozzles (720-1-720-3) may be used to release a top wafer as the direct bond front propagates outwards. In an embodiment, when measured bond front propagation data collected during the wafer bonding method indicate a deviance from a desired tolerance, such as an excessive degree of eccentricity of propagation of the bond front, corrective action with respect to the various vacuum nozzles (720-1-720-3) can be taken to reduce the eccentricity. For example, the various vacuum nozzles (720-1-720-3) can be controlled with a desired vacuum pressure, such as to release the top wafer in situ during bond front propagation at such times and radial locations where the bond front has propagated too slowly, such as to accelerate the bond front. In other cases, the desired vacuum pressure may be maintained longer at such times and radial locations where the bond front has propagated too quickly, such as to retard the bond front.

In similar embodiments, the first wafer holder 715 comprises a first vacuum nozzle 710-1 disposed in a center of the first wafer holder 715, a plurality of second vacuum nozzles 710-2 disposed around the first vacuum nozzle 710-1, and a plurality of third vacuum nozzles 710-3 disposed around the first vacuum nozzle 710-1 at a larger radial distance than the plurality of second vacuum nozzles 710-2. Various other arrangements and numbers of vacuum nozzles can be used in different embodiments. For example, a number or a size of vacuum nozzles can vary in different embodiments. In some embodiments, different diameters of vacuum nozzles can be used together.

The first wafer holder 715 may be substantially flat or planar, and concentric chucking zones (the various vacuum nozzles (710-1-710-4)) may be distributed to enable a variable thickness layer disposed over a backside of a wafer to be flattened during the chucking on the first wafer holder 715. For example, a distance between adjacent chucking zones (vacuum nozzles) may decrease moving from the center to the outer edge of the first wafer holder 715 such that there is a higher density of chucking sites (or vacuum channels or electrodes) at the edges of the first wafer holder 715 than the center.

In other embodiments, the first wafer holder 715 and the second wafer holder 725 may be electrostatic chucks (ESCs) comprising electrodes in the concentric chucking zones instead of the various vacuum nozzles (710-1-710-4, and 720-1-720-4).

FIG. 8 illustrates cross-sectional views of the first wafer 10 comprising the variable thickness layer 106 during various steps of a method of loading the first wafer 10 on a wafer holder 815 such that the variable thickness layer 106 contacts the wafer holder 815. Steps 80a-c illustrate various steps of activating different vacuum nozzles to load the first wafer 10 on the wafer holder 815 to form a symmetrical stretch in the first wafer 10 by pulling down the variable thickness layer 106.

Step 80a illustrates the first wafer 10 loaded on the wafer holder 815 such that the variable thickness layer 106 contacts a first activated vacuum nozzle 820-1, which may be activated to receive the first wafer 10. After receiving the first wafer 10, various vacuum nozzles (810-2-810-4) may be activated to form a symmetrical stretch in the first wafer 10 as desired. As an example, step 80b activates the plurality of second vacuum nozzles 810-2 such that a plurality of second activated vacuum nozzles 820-2 pulls the first wafer 10 down to start forming a first symmetrical stretch (s₁) across the first wafer 10 according to the thickness gradient of the variable thickness layer 106. And further, step 80c activates the plurality of third vacuum nozzles 810-3 and the plurality of fourth vacuum nozzles 810-4 such that a plurality of third activated vacuum nozzles 820-3 and a plurality of fourth activated vacuum nozzles 820-4 finish the loading of the first wafer 10 in the wafer holder 815. And the full activation of all of the vacuum zones (820-1-820-4) of the wafer holder 815 in step 80c forms a second symmetrical stretch (s₂) in the first wafer 10 according to the thickness gradient of the variable thickness layer 106 as may be desired to compensate for potential scaling in the bonded wafer. In other embodiments, different activation sequences may be utilized to pull the variable thickness layer 106 into contact with the wafer holder 815 and form the second symmetrical stretch (s₂) in the first wafer 10 as desired.

FIGS. 9-10 are flowcharts illustrating example methods of bonding wafers using a variable thickness layer in accordance with embodiments of this disclosure. The methods of FIGS. 9-10 may be combined with other methods and performed using suitable systems and apparatuses as described herein, such as the wafer bonding method of FIGS. 1A-1J, the processing methods to deposit a variable thickness layer of FIGS. 3A-3C and 4A-4C, and by using the wafer bonding apparatus 60 of the wafer bonding system 600 of FIGS. 6A-6B. Although shown in a logical order, the arrangement and numbering of the steps of FIGS. 9-10 are not intended to be limiting.

Referring to FIG. 9, step 910 of a method 900 of bonding wafers deposits a dielectric layer on a first side of a first wafer, the dielectric layer comprising a first thickness at a first location and a second thickness at a second location, the first thickness being different from the second thickness. In various embodiments, the first wafer may be the first wafer 10 of FIGS. 1A-1J, the first wafer 61 of FIG. 6A, or the wafer 30 of FIGS. 3A-3C and FIGS. 4A-4C. In those embodiments, the dielectric layer may be the variable thickness layer 106 of FIG. 1B comprising the center thickness (t_{c}) and the edge thickness (tₑ), or the variable thickness layer 65 of FIG. 6A, or the variable thickness layer 414 of FIG. 4C, or the variable thickness layer 306c of FIG. 3C. In similar embodiments, the deposition of the dielectric layer over the backside of the first wafer in step 910 may be illustrated by FIGS. 1B, 3A-3C, and 4A-4C. In other embodiments, the deposition in step 910 may be performed after forming an object layer or a stepped structure through a multi-patterning process such as described above for the object layer 410 of FIGS. 4A-4C. Additionally, step 910 may be the step 220 of the wafer bonding method 200 in FIG. 2. The first thickness may be the center thickness (t_{c}) and the second thickness may be the edge thickness (tₑ), where the first location may be the center region and the second location may be the edge region of the first wafer 10.

After, the method 900 loads the first wafer on a planar surface of a first wafer holder in step 920, the first wafer holder comprising concentric chucking zones. In one or more embodiments, the first wafer holder may be a vacuum chuck. In those embodiments, the first wafer holder may be the first wafer holder 115 of FIGS. 1C-1J, the first wafer holder 615 of the wafer bonding apparatus 60 of FIG. 6A, the first wafer holder 715 of FIG. 7, or the wafer holder 815 of FIG. 8. In those same embodiments, the concentric chucking zones may comprise the various vacuum nozzles of the corresponding wafer holders in FIGS. 1C-1J, 6A, 7, and 8. In other embodiments, the concentric chucking zones may comprise electrodes and the first wafer holder may be an electrostatic chuck (ESC). Step 920 may be the step of the wafer bonding method illustrated in FIG. 1C, or step 230 of the wafer bonding method 200 in FIG. 2.

In step 930, the method 900 activates the concentric chucking zones from a center to an outer edge of the first wafer holder to align an outer surface of the dielectric layer with the planar surface of the first wafer holder while stretching the first wafer. The loading of the first wafer on the first wafer holder in step 930 may comprise the steps (80a-c) of loading the first wafer 10 in the wafer holder 815 by activating the various vacuum nozzles (810-1-810-4). Additionally, a stretch formed in the first wafer by the chucking onto the first wafer holder may be the second symmetrical stretch (s₂) illustrated in FIG. 8. Step 930 may be the step of the wafer bonding method illustrated in FIG. 1D, or the step 230 of the wafer bonding method 200 in FIG. 2.

After chucking the first wafer to the first wafer holder in step 930, the method 900 may proceed to step 940. In step 940, the method 900 aligns a second wafer on a second wafer holder opposite the first wafer, the second wafer being separated from the first wafer by a separation distance. In various embodiments, the second wafer may be the second wafer 20 of FIG. 1E; the separation distance may be the separation distance (dₛ) of FIG. 1E; and the second wafer holder may be the second wafer holder 135 of FIG. 1E, the second wafer holder 625 of FIG. 6A, or the second wafer holder 725 of FIG. 7. Step 940 may be the step of the wafer bonding method illustrated in FIG. 1E, or steps 240-250 of the wafer bonding method 200 in FIG. 2.

In step 950, the method 900 bonds the first wafer with the second wafer to form a bonded wafer, the bonding comprising striking the second wafer towards the first wafer to stretch the second wafer complimentary with the stretching of the first wafer. In various embodiments, the bonding in step 950 may be the striking 134 of FIG. 1F, and the bonded wafer may be the bonded wafer 100 formed in FIGS. 1F-1J. Step 950 may be step 260 of the wafer bonding method 200 of FIG. 2. After forming the bonded wafer in step 950, other embodiments may proceed to perform further processing steps. For example, a step to remove the dielectric layer (such as step 270 of FIG. 2), or a step to anneal the bonded wafer (such as step 280 of FIG. 2). In various embodiments, the method 900 may be the wafer bonding method of FIGS. 1A-1J or the wafer bonding method 200 of FIG. 2.

Now referring to FIG. 10, step 1010 of a method 1000 of bonding wafers receives a wafer such that a backside of the wafer faces a processing nozzle, the wafer comprising a uniform thickness shape disposed over the backside of the wafer. In various embodiments, the wafer may be the first wafer 10 of FIGS. 1A-1J, or the wafer 30 of FIGS. 3A-3C and 4A-4C. The uniform thickness shape may be the object layer 410 of FIGS. 4A-4C or the first object layer 510 of FIG. 5A or the second object layer 520 of FIG. 5B. Step 1010 may be illustrated by FIG. 1A or step 210 of the wafer bonding method 200 in FIG. 2. Additionally, step 1010 may be the step illustrated in FIG. 3A or FIG. 4A.

After, in step 1020, the method 1000, while rotating the wafer, dispenses a processing solution over the backside of the wafer form the processing nozzle to form a variable thickness layer covering the backside of the wafer, the variable thickness layer comprising a first region comprising a first thickness, a second region comprising a second thickness, and a transition region comprising a variable thickness that smoothly transitions between the first thickness and the second thickness. In various embodiments, the first region and the first thickness may be the center thickness (t_{c}) and the second region and the second thickness may be the edge thickness (tₑ) at the edge region of the first wafer 10. In those same embodiments, the transition region may be the region between the center and edges of the first wafer 10 comprising the smooth transition in step height between the center thickness (t_{c}) and the edge thickness (tₑ). Additionally, step 1020 may be the steps illustrated in FIG. 3A, and 4B through the dispensing (or flow 336) of the processing solution 412.

Still referring to FIG. 10, in step 1030, the method 1000 loads the wafer on a wafer holder by sequentially activating concentric chucking zones form a center to an outer edge of the wafer holder such that the variable thickness layer contacts the wafer holder and flattens to form a symmetrical stretch in the wafer. Step 1030 may be illustrated by steps 80a-c of FIG. 8, or the step illustrated in FIGS. 1C-1D. Further, step 1030 may be step 230 of the wafer bonding method 200 of FIG. 2. And step 1040 of the method 1000 bonds the wafer with a second wafer to form a bonded wafer. In various embodiments, step 1040 may be illustrated by FIGS. 1E-1J, and may be steps 240-260 of the wafer bonding method 200 in FIG. 2. Similarly, the method 1000 may perform additional processing steps after step 1040 to further form the bonded wafer, such as removing the variable thickness layer and annealing the bonded wafer (in either order).

The embodiment bonding methods of this disclosure mitigate wafer scaling by inducing approximately the same dilation in both wafers by using the variable thickness layer. As a result, the bonding method of this disclosure may produce bonded wafers comprising improved alignment.

Example embodiments of the invention are described below. Other embodiments can also be understood from the entirety of the specification as well as the claims filed herein.
Example 1. A method for bonding wafers includes depositing a dielectric layer on a first side of a first wafer, the dielectric layer including a first thickness at a first location and a second thickness at a second location, the first thickness being different from the second thickness, and loading the first wafer on a planar surface of a first wafer holder, the first wafer holder including concentric chucking zones. The method further includes activating the concentric chucking zones from a center to an outer edge of the first wafer holder to align an outer surface of the dielectric layer with the planar surface of the first wafer holder while stretching the first wafer, and aligning a second wafer on a second wafer holder opposite the first wafer, the second wafer being separated from the first wafer by a separation distance. And the method further includes bonding the first wafer with the second wafer to form a bonded wafer, the bonding including striking the second wafer towards the first wafer to stretch the second wafer complimentary with the stretching of the first wafer.
Example 2. The method of example 1, further including annealing the bonded wafer, and removing the dielectric layer from the bonded wafer.
Example 3. The method of one of examples 1 or 2, where the dielectric layer includes the first thickness between 1 μm and 200 μm, and the second thickness between 100 nm and 20 μm, where the separation distance varies between 1 μm and 200 μm, and where the first thickness is larger than the second thickness.
Example 4. The method of one of examples 1 to 3, where the dielectric layer includes dielectric material, polydimethylsiloxane (PDMS), polyurethane, epoxy resin, photoresist, or acrylic polymer.
Example 5. The method of one of examples 1 to 4, where the first wafer holder includes a vacuum chuck, and the concentric chucking zones include vacuum nozzles.
Example 6. The method of one of examples 1 to 5, where the first wafer holder includes an electrostatic chuck, and the concentric chucking zones include electrodes.
Example 7. The method of one of examples 1 to 6, where depositing the dielectric layer includes spin-coating the first side of the first wafer.
Example 8. The method of one of examples 1 to 7, where depositing the dielectric layer includes forming an object layer over the first side of the first wafer, the object layer including a shape and an object thickness, and spin-coating the object layer and the first side of the first wafer to form the dielectric layer, the object layer defining a thickness gradient of the dielectric layer.
Example 9. The method of one of examples 1 to 8, where the object layer includes a stepped structure, and where forming the object layer includes performing a multi-patterning process to form the stepped structure over the first side of the first wafer, the multi-patterning process including depositing a photoreactive layer, exposing the photoreactive layer through a photo mask, and removing unexposed portions of the photoreactive layer.
Example 10. The method of one of examples 1 to 9, where the shape includes an ellipse, a cross, or a polygon, and where the object thickness varies between 1 μm and 200 μm.
Example 11. A method for bonding a wafer includes receiving the wafer such that a backside of the wafer faces a processing nozzle, the wafer including a uniform thickness shape disposed over the backside of the wafer. The method further includes, while rotating the wafer, dispensing a processing solution over the backside of the wafer from the processing nozzle to form a variable thickness layer covering the backside of the wafer, the variable thickness layer including a first region including a first thickness, a second region including a second thickness, and a transition region including a variable thickness that smoothly transitions between the first thickness and the second thickness. And the method further includes loading the wafer on a wafer holder by sequentially activating concentric chucking zones from a center to an outer edge of the wafer holder such that the variable thickness layer contacts the wafer holder and flattens to form a symmetrical stretch in the wafer, and bonding the wafer with a second wafer to form a bonded wafer.
Example 12. The method of example 11, where the uniform thickness shape defines the first region of the variable thickness layer, an outer edge of the wafer defines the second region of the variable thickness layer, and a region between the first region and the second region define the transition region of the variable thickness layer.
Example 13. The method of one of examples 11 or 12, where the variable thickness layer includes the first thickness between 1 μm and 200 μm, and the second thickness between 100 nm and 20 μm.
Example 14. The method of one of examples 11 to 13, where the uniform thickness shape includes an ellipse, a cross, or a polygon, and where the uniform thickness shape includes a thickness between 1 μm and 200 μm.
Example 15. The method of one of examples 11 to 14, where the processing solution includes dielectric material, polydimethylsiloxane (PDMS), polyurethane, epoxy resin, photoresist, or acrylic polymer.
Example 16. The method of one of examples 11 to 15, where the variable thickness layer includes dielectric material, polydimethylsiloxane (PDMS), polyurethane, epoxy resin, photoresist, or acrylic polymer.
Example 17. A system for bonding wafers includes a bonding chamber including a second wafer holder disposed over a first wafer holder, the second wafer holder including a striker disposed in a center of the second wafer holder, the first wafer holder including concentric chucking zones, and a controller coupled to the bonding chamber, the first wafer holder, the second wafer holder, and a memory storing instructions to be executed in the controller. The instructions when executed cause the controller to deposit a dielectric layer on a first side of a first wafer, the dielectric layer including a first thickness at a first location and a second thickness at a second location, the first thickness being different from the second thickness, load the first wafer on a planar surface of the first wafer holder, activate the concentric chucking zones from a center to an outer edge of the first wafer holder to align an outer surface of the dielectric layer with the planar surface of the first wafer holder while stretching the first wafer, align a second wafer on the second wafer holder opposite the first wafer, the second wafer being separated from the first wafer by a separation distance, and bond the first wafer with the second wafer to form a bonded wafer, the bonding including striking the second wafer towards the first wafer to stretch the second wafer complimentary with the stretching of the first wafer using the striker.
Example 18. The system of example 17, where the first wafer holder includes a vacuum chuck, the concentric chucking zones include vacuum nozzles, and the second wafer holder includes a vacuum chuck.
Example 19. The system of one of examples 17 or 18, where the first wafer holder includes an electrostatic chuck, the concentric chucking zones include electrodes, and the second wafer holder includes an electrostatic chuck.
Example 20. The system of one of examples 17 to 19, where the dielectric layer includes the first thickness between 1 μm and 200 μm, and the second thickness between 100nm and 20 μm, and where the separation distance varies between 1 μm and 200 μm.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for bonding wafers, the method comprising:
depositing a dielectric layer on a first side of a first wafer, the dielectric layer comprising a first thickness at a first location and a second thickness at a second location, the first thickness being different from the second thickness;
loading the first wafer on a planar surface of a first wafer holder, the first wafer holder comprising concentric chucking zones;
activating the concentric chucking zones from a center to an outer edge of the first wafer holder to align an outer surface of the dielectric layer with the planar surface of the first wafer holder while stretching the first wafer;
aligning a second wafer on a second wafer holder opposite the first wafer, the second wafer being separated from the first wafer by a separation distance; and
bonding the first wafer with the second wafer to form a bonded wafer, the bonding comprising striking the second wafer towards the first wafer to stretch the second wafer complimentary with the stretching of the first wafer.

2. The method of claim 1, further comprising annealing the bonded wafer, and removing the dielectric layer from the bonded wafer.

3. The method of claim 1, wherein the dielectric layer comprises the first thickness between 1 μm and 200 μm, and the second thickness between 100 nm and 20 μm, wherein the separation distance varies between 1 μm and 200 μm, and wherein the first thickness is larger than the second thickness.

4. The method of claim 1, wherein the dielectric layer comprises dielectric material, polydimethylsiloxane (PDMS), polyurethane, epoxy resin, photoresist, or acrylic polymer.

5. The method of claim 1, wherein the first wafer holder comprises a vacuum chuck, and the concentric chucking zones comprise vacuum nozzles.

6. The method of claim 1, wherein the first wafer holder comprises an electrostatic chuck, and the concentric chucking zones comprise electrodes.

7. The method of claim 1, wherein depositing the dielectric layer comprises spin-coating the first side of the first wafer.

8. The method of claim 1, wherein depositing the dielectric layer comprises:
forming an object layer over the first side of the first wafer, the object layer comprising a shape and an object thickness; and
spin-coating the object layer and the first side of the first wafer to form the dielectric layer, the object layer defining a thickness gradient of the dielectric layer.

9. The method of claim 8, wherein the object layer comprises a stepped structure, and wherein forming the object layer comprises performing a multi-patterning process to form the stepped structure over the first side of the first wafer, the multi-patterning process comprising depositing a photoreactive layer, exposing the photoreactive layer through a photo mask, and removing unexposed portions of the photoreactive layer.

10. The method of claim 8, wherein the shape comprises an ellipse, a cross, or a polygon, and wherein the object thickness varies between 1 μm and 200 μm.

11. A method for bonding a wafer, the method comprising:
receiving the wafer such that a backside of the wafer faces a processing nozzle, the wafer comprising a uniform thickness shape disposed over the backside of the wafer;
while rotating the wafer, dispensing a processing solution over the backside of the wafer from the processing nozzle to form a variable thickness layer covering the backside of the wafer, the variable thickness layer comprising a first region comprising a first thickness, a second region comprising a second thickness, and a transition region comprising a variable thickness that smoothly transitions between the first thickness and the second thickness;
loading the wafer on a wafer holder by sequentially activating concentric chucking zones from a center to an outer edge of the wafer holder such that the variable thickness layer contacts the wafer holder and flattens to form a symmetrical stretch in the wafer; and
bonding the wafer with a second wafer to form a bonded wafer.

12. The method of claim 11, wherein the uniform thickness shape defines the first region of the variable thickness layer, an outer edge of the wafer defines the second region of the variable thickness layer, and a region between the first region and the second region define the transition region of the variable thickness layer.

13. The method of claim 11, wherein the variable thickness layer comprises the first thickness between 1 μm and 200 μm, and the second thickness between 100 nm and 20 μm.

14. The method of claim 11, wherein the uniform thickness shape comprises an ellipse, a cross, or a polygon, and wherein the uniform thickness shape comprises a thickness between 1 μm and 200 μm.

15. The method of claim 11, wherein the processing solution comprises dielectric material, polydimethylsiloxane (PDMS), polyurethane, epoxy resin, photoresist, or acrylic polymer.

16. The method of claim 11, wherein the variable thickness layer comprises dielectric material, polydimethylsiloxane (PDMS), polyurethane, epoxy resin, photoresist, or acrylic polymer.

17. A system for bonding wafers, the system comprising:
a bonding chamber comprising a second wafer holder disposed over a first wafer holder, the second wafer holder comprising a striker disposed in a center of the second wafer holder, the first wafer holder comprising concentric chucking zones; and
a controller coupled to the bonding chamber, the first wafer holder, the second wafer holder, and a memory storing instructions to be executed in the controller, the instructions when executed cause the controller to:
deposit a dielectric layer on a first side of a first wafer, the dielectric layer comprising a first thickness at a first location and a second thickness at a second location, the first thickness being different from the second thickness,
load the first wafer on a planar surface of the first wafer holder,
activate the concentric chucking zones from a center to an outer edge of the first wafer holder to align an outer surface of the dielectric layer with the planar surface of the first wafer holder while stretching the first wafer,
align a second wafer on the second wafer holder opposite the first wafer, the second wafer being separated from the first wafer by a separation distance, and
bond the first wafer with the second wafer to form a bonded wafer, the bonding comprising striking the second wafer towards the first wafer to stretch the second wafer complimentary with the stretching of the first wafer using the striker.

18. The system of claim 17, wherein the first wafer holder comprises a vacuum chuck, the concentric chucking zones comprise vacuum nozzles, and the second wafer holder comprises a vacuum chuck.

19. The system of claim 17, wherein the first wafer holder comprises an electrostatic chuck, the concentric chucking zones comprise electrodes, and the second wafer holder comprises an electrostatic chuck.

20. The system of claim 17, wherein the dielectric layer comprises the first thickness between 1 μm and 200 μm, and the second thickness between 100 nm and 20 μm, and wherein the separation distance varies between 1 μm and 200 μm.
